(19) United States
(12) Patent Application Publication
(10) Pub. No.: US 2022/0413391 A1
(43) Pub. Date: Dec. 29, 2022

(54) METHOD AND APPARATUS FOR DETERMINING CONTROL DATA FOR A LITHOGRAPHIC APPARATUS

(71) Applicant: ASML NETHERLANDS B.V., Veldhoven (NL)

(72) Inventors: Michel Alphons Theodorus VAN HINSBERG, Eindhoven (NL); James Robert DOWNES, Eindhoven (NL); Erwin Josef Maria VERDURMEN, Geldrop (NL); Jacob Fredrik Friso KLINKHAMER, Tilburg (NL); Roy WERKMAN, Eindhoven (NL); Jochem Sebastiaan WILDENBERG, Aarle-Rixtel (NL); Adam Jan URBANCZYK, Utrecht (NL); Lucas Jan Joppe VISSER, 's-Hertogenbosch (NL)

(73) Assignee: ASML NETHERLANDS B.V., Veldhoven (NL)

(21) Appl. No.: 17/777,348

(22) PCT Filed: Oct. 15, 2020
(86) PCT No.: PCT/EP2020/078986

§ 371 Date: May 17, 2022

(30) Foreign Application Priority Data
Nov. 21, 2019 (EP) 19210585.6
Dec. 19, 2019 (EP) 19218161.8
Mar. 10, 2020 (EP) 20161954.1

(51) Int. Cl. G03F 7/20

(52) U.S. Cl. CPC G03F 7/705; G03F 7/70525

(57) ABSTRACT

A method for determining an input to a lens model to determine a setpoint for manipulation of a lens of a lithographic apparatus when addressing at least one of a plurality of fields of a substrate, the method including: receiving parameter data for the at least one field, the parameter data relating to one or more parameters of the substrate within the at least one field, the one or more parameters being at least partially sensitive to manipulation of the lens as part of an exposure performed by the lithographic apparatus; receiving lens model data relating to the lens; and determining the input based on the parameter data and on the lens model data.

### CROSS-REFERENCE TO RELATED APPLICATIONS

This application claims priority of EP application 19210585.6 which was filed on Nov. 21, 2019 and EP application 19218161.8 which was filed on Dec. 19, 2019 and EP application 20161954.1 which was filed on Mar. 10, 2020 which are incorporated herein in its entirety by reference.

### FIELD

The present invention relates to methods and apparatus for determining control data for a lithographic apparatus. In particular, it may relate to determining a request for input to a lens model to determine a setpoint for manipulation of a lens of a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

To monitor the quality and performance of a lithographic patterning process, inspections of patterns exposed by the lithographic apparatus may be performed. These inspections can include several types of measurements performed by different types of metrology tools. The measurements may be used to monitor different parameters of the patterned substrate. The measurements may be used to identify one or more errors in the exposed patterns, and associated corrections to a lithographic patterning process may be determined based on the identified errors. These corrections may be applied to the lithographic patterning process in order to improve future exposures performed by the lithographic apparatus. In order to determine how to update a lithographic patterning process, models may be used to link an identified error and/or a desired correction to an update or adjustment to the lithographic process settings. In order to improve the output of the model and obtain better results, the data provided as input to the model may be optimized.

### SUMMARY

According to an aspect of the current disclosure there is provided a method for determining control data for a lithographic apparatus. The method comprises receiving parameter data associated with a plurality of fields on the substrate. The parameter data is provided as an input to a cost function. The method further comprises evaluating the cost function extending across the plurality of fields, wherein the cost function is based on control characteristic of the lithographic apparatus. The cost function provides an output comprising a correction configured to reduce a residual of a performance parameter across the plurality of fields of the substrate. The method may further comprise determining control data based on the output.

Optionally, the control characteristics of the lithographic apparatus may comprise one or more boundary conditions for the correction.

Optionally, the cost function may determine control data to minimise the residual of the performance parameter across the plurality of fields.

Optionally, the correction may comprise actuator control settings for at least one actuator of the lithographic apparatus.

Optionally, the control data may comprise a routing order for exposure of the plurality of fields.

Optionally, the output may comprise a routing order for exposure of the plurality of fields.

Optionally, the method may further comprise determining a preparation time to be provided to the lithographic for implementing control data. Boundary conditions for the correction may be determined based at least in part on the preparation time.

Optionally, determining a preparation time may comprise determining a residual of a performance parameter for a first preparation time for one or more fields. Determining a preparation time may further comprise determining a residual of a performance parameter for a second preparation time for the one or more fields, wherein the second preparation time is longer than the first preparation time. One of the first preparation time and the second preparation time may be selected as the preparation time to be provided to the lithographic apparatus. The selection may be based on a comparison of the residuals for the first preparation time and the second preparation time to a threshold residual value.

Optionally, the threshold residual value may represent an upper limit for a residual resulting in a functioning field.

According to another aspect of the current disclosure there is provided an apparatus for determining control data for a lithographic apparatus, the apparatus comprising one or more processors configured to perform a method as described above.

In an aspect of the invention a method for determining an input to a lens model to determine a setpoint for manipulation of a lens of a lithographic apparatus when addressing at least one of a plurality of fields of a substrate is provided, the method comprising: receiving parameter data for the at least one field, the parameter data relating to one or more parameters of the substrate within the at least one field, the one or more parameters being at least partially sensitive to manipulation of the lens as part of an exposure performed by the lithographic apparatus; receiving lens model data relating to the lens; and determining the input based on the parameter data and on the lens model.

Optionally, the at least one field may comprise a partial field. The parameter data may comprise parameter data relating to locations inside the partial field. Determining the input may comprise optimizing the input to apply a correction to the one or more parameters, wherein the correction may be identified by the parameter data relating to the locations within the partial field.

Optionally, optimizing the input may comprise determining an initial setpoint inside of the partial field based on a first lens model, wherein the first lens model is based on the lens model data, and evaluating the initial setpoint to determine a setpoint across a portion for a full field outside of the partial field to determine a target setpoint.

Optionally, the first lens model may be further configured to determine an input corresponding to the target setpoint.

Optionally, the first lens model may be a partial field aware lens model configured not to optimize the input for locations outside of the partial field.

Optionally, optimizing the input may comprise determining a plurality of provisional inputs based on the parameter data, and selecting one of the plurality of provisional inputs based on the lens model data.

Optionally, determining one or more of the plurality of provisional inputs may comprise extrapolating parameter data outside of the partial field based on the parameter data inside of the partial field.

Optionally, selecting the one of the plurality of provisional inputs may comprise selecting a provisional input that applies a correction to the parameter that is closest to the correction identified from the parameter data.

Optionally, the correction may be of an error identified in the parameter data.

Optionally, the lens model data may comprise a copy of the lens model.

Optionally, the lens model data may comprise dynamic data for the lens.

Optionally, determining the input may comprise determining an input for a first field based on an input for a second field.

Optionally, the first field may be a partial field and the second field is a full field.

Optionally, the partial field may be adjacent to the full field.

Optionally, the input may be further determined based on dynamic data for the lens and/or an importance of the partial field and/or the full field.

Optionally, the importance of the full field may be greater than an importance of the partial field.

Optionally, the importance of the partial field and/or the full field may be based on the number of structures to be patterned in the field and/or the dimensions of at least a portion of the structures to be patterned in the field.

Optionally, determining the input may comprise optimizing the input to apply a corrections to the parameters in the full field.

Optionally, the parameter data may comprise partial field parameter data and full field parameter data. Optimizing the input may comprise determining an input for the full field based on the full field parameter data, and determining an input for the partial field based on the partial field parameter data and using the input for the full field as a constraint.

Optionally, the parameter data may comprise metrology data.

Optionally, manipulation of the lens may comprise setting a location of one or more lens manipulators, wherein the lens manipulators may be configured to apply a deformation to the lens.

Optionally, the one or more parameters may comprise one or more of overlay data, critical dimension data, levelling data, alignment data, or edge placement error data.

Optionally, the parameter data may be associated with one or more of pattern shift, overlay, alignment aberrations, or focus errors.

Optionally, the method may further comprise providing the input to the lens model, and determining, based on the lens model, the setpoint for manipulation of the lens.

Optionally, the method may further comprise providing the setpoint to the lens. The lithographic apparatus may be configured to perform a lithographic exposure of a substrate using the provided lens setpoint.

According to another aspect of the current disclosure there is provided an apparatus for configuring an input to a lens model for determining one or more settings of a lens of a lithographic apparatus, the apparatus comprising one or more processors configured to perform a method as described above.

According to another aspect of the current disclosure there is provided a lithographic apparatus comprising an apparatus as described above.

According to another aspect of the current disclosure there is provided a lithographic cell comprising an apparatus as described above.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 depicts a flow diagram comprising steps in a method for determining control data for a lithographic apparatus; and

FIG. 5(a) depicts a routing order for an exposure sequence following a typical exposure meander, for example following neighbouring field positions;

FIG. 5(b) depicts a routing order for an exposure sequence based on a determined correction value;

FIG. 6 depicts a flow diagram with steps in a method for determining preparation time available to the lithographic apparatus;

FIG. 7 depicts a flow diagram comprising steps in a method of determining an input to a lens model;

FIG. 8(a) depicts a portion of a substrate comprising an edge field;

FIG. 8(b) depicts a schematic representation of extrapolated data;

FIG. 9 depicts a schematic representation of steps in a method for determining a setpoint for manipulation of a lens;

FIG. 10 depicts an example first lens model for determining an input to a lens model;

FIG. 11 depicts an example first lens model for determining an input to a lens model;

FIG. 12 depicts a schematic representation of a portion of a substrate comprising a plurality of fields for which a setpoint has been determined;

FIG. 13 depicts a schematic representation of steps in a method for determining an input to a lens model.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

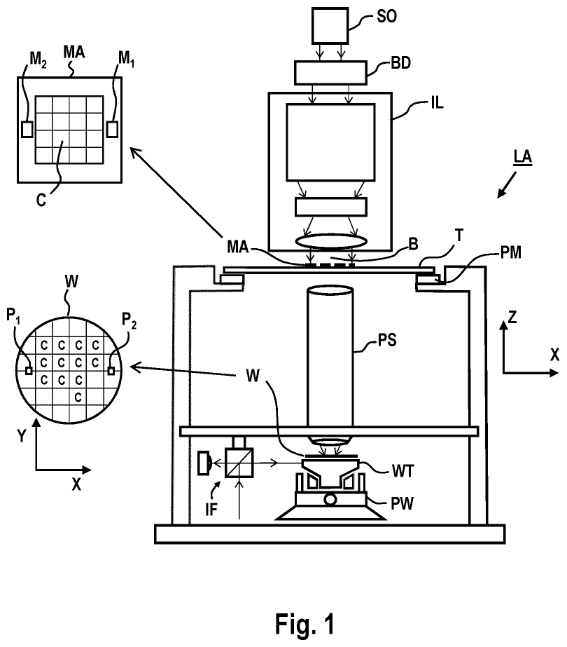

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support T, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

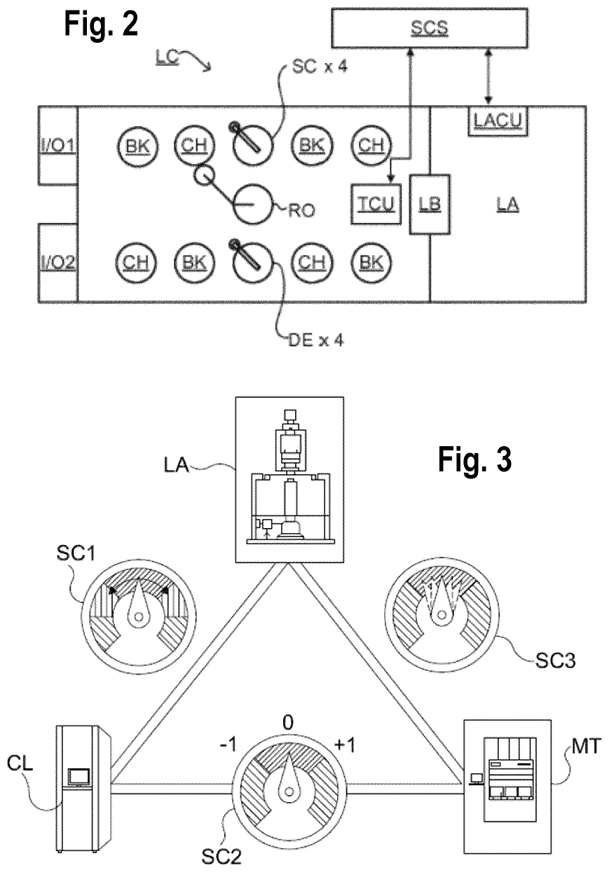

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

Different types of metrology tools MT may be used alongside a lithographic apparatus LA, in order to measure different aspects or properties of patterns lithographically exposed on a substrate. Metrology tools MT may use radiation, such as electromagnetic radiation, to interrogate a pattern on a substrate. A metrology tool MT may for example comprise a scatterometer. Example properties that may be measured by a metrology tool TM to determine a quality of an exposure include overlay OVL, alignment AL, and levelling data LVL.

Metrology tools MT may be used to inspect the quality and/or properties of patterns exposed on a substrate. This inspection may be used to detect errors in the exposed pattern. Identified errors may be analysed to determine updates to the settings of the lithographic apparatus, to improve future exposures by the lithographic apparatus, for example by partially or wholly removing the patterning errors from subsequent exposures of the same pattern. One of the elements of a lithographic exposure that may be amended in response to the detection of a patterning error is the properties of the radiation beam used to expose the substrate. A lithographic apparatus LA may control the settings of the radiation source, for example to control power, pulse duration, etc. of the radiation. A lithographic apparatus LA may control properties (e.g. speed, routing, etc.) of the trajectory along which a plurality of fields are exposed on the wafer. A lithographic apparatus LA may comprise an optical assembly for controlling and manipulating the radiation beam used for a lithographic exposure. Described herein are methods and apparatus for determining updates to control settings relating to one or more of the above elements of the apparatus LA, or any other features affecting the patterning process performed by the lithographic apparatus LA. The control settings may be determined separately or in combination with each other.

A substrate exposed by a lithographic apparatus LA may comprise errors introduced by different elements controlling the exposure process. Parameter data of one or more parameters on one or multiple previously exposed substrates may be used to identify errors present on a patterned substrate. The identified errors may be residual errors present in a parameter indicative of a quality of the exposed pattern/performance of the patterning process. Analysis of identified errors may be performed to determine how the errors may be addressed and compensated for in subsequent exposures. An exposure may be performed by implementing a patterning recipe (also referred to as an exposure recipe) by a lithographic apparatus. Corrections to the recipe may be determined to remove/reduce errors in future exposures based on the identified errors in previous exposures. These corrections may be implemented in the form of changes/corrections to control settings of one or more actuators inside the lithographic apparatus. The actuators may be elements of the lithographic apparatus that control an aspect of the exposure process (e.g. radiation source, radiation control (e.g. by a lens), stage/substrate control, etc.). It is an aim of the methods and apparatus described herein to improve the control of the lithographic apparatus LA to reduce the errors in exposed patterns. Specifically, the methods may be used to reduce a residual error in patterns exposed by the lithographic apparatus LA.

The parameter data of a substrate may comprise metrology data. Metrology data may be of a lithographically patterned substrate. Metrology data may comprise data relating to one or more parameters of the substrate and/or a structure patterned on the substrate. This may be referred to as parameter data. Next to metrology data, other forms of parameter data may be provided for a substrate, for example simulated parameter data. The parameter data may be provided per exposure field on a substrate. One or more corrections for a pattern may be determined based on parameter data. The parameter data may be of a previous exposure of a pattern on one or more substrates. The pattern of the one or more previous exposures may be the same as the pattern to be exposed. The parameter data may comprise metrology data and/or simulation data of an exposed pattern on a substrate. The parameter data may be provided for a plurality of locations across the substrate.

Based on the parameter data, errors in the parameter values present in the parameter data may be identified. This may for example be done by comparing the parameter data for a substrate to expected values of those parameters. Errors of parameter data may represent aberrations of parameter values of a substrate that deviate from expected values for those parameters. The parameter data may comprise data relating to an error in a parameter value in addition to or alternatively to parameter values themselves. The identified errors may also be considered an indication of corrections to be applied to an exposed pattern in order to remove the identified error. The corrections to a pattern may be translated into corrections to a lithographic patterning process for exposing that pattern. These corrections may be applied to a lithographic patterning process so that future exposures of the same pattern as the one for which parameter data was provided can be improved.

In order to determine patterning errors on an exposed substrate parameter data may be provided to a cost function. A cost function may be used to determine how to correct for errors in a patterning process, based on parameter data from previously exposed substrate(s). As computational cost for determining corrections may be high, calculations and other analysis may be performed on individual exposure fields separately. The calculations and analysis applied may be the same for each field. This may bring down overall computational cost across the substrate, and may decrease the required calculation time. However, using such a simplified approach of separately determining corrections for different fields may mean the determined corrections are not optimal. For example, the corrections applied in preceding and succeeding fields to a field to be exposed may affect the corrections that can be achieved, as the actuators may have limitations (e.g. speed, range, direction) to the type/range of change to control settings that can be implemented between subsequently exposed fields. Furthermore, in some instances, not all fields should be analysed in the same manner. For example, edge fields may have different shapes to each other and to inner fields on the substrate. Furthermore, some fields on the substrate may comprise patterning structures that have higher or lower tolerance for exposure errors. The cost functions described herein are able to address at least some of the problems and challenges described herein.

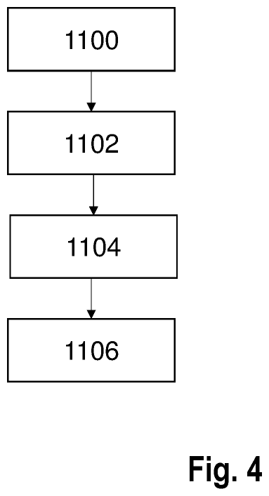

Generally disclosed herein is a method for determining control data for a lithographic apparatus as depicted in FIG. 4. In step 1100 the method receives parameter data associated with a plurality of fields on a substrate. The plurality of fields may for example be all the fields on an exposed substrate layer. In step 1102 the parameter data for the plurality of fields is provided as input to a cost function. The cost function has knowledge of the lithographic apparatus. The cost function may be based on control characteristics of the lithographic apparatus. The cost function may extend across a plurality of fields, meaning it may perform analysis taking into account a plurality of fields. In step 1104, the cost function and input are evaluated to obtain an output. The output comprises a correction. The correction may be a correction to the patterning recipe to be exposed by the lithographic apparatus. Specifically, the correction may reduce a residual of a performance parameter across the plurality of fields on the substrate. In step 1106 the control data may be determined based on the cost function output.

An advantage of the cost function as described above, is that the correction configured to reduce a patterning error may be determined for a plurality of fields, meaning that effects of corrections of previous and subsequent fields on each other may be taken into account. This may lead to an increased correction potential. For example, actuator range and speed limitations may be determined for each field in relation to the settings of the previously exposed field. This increases the overall correction range available to the substrate.

An advantage of using a cost function based on knowledge of control characteristics of the apparatus may be that the cost function can correct for residual errors introduced by the lithographic apparatus controls. That is to say, there may be a difference between the design requested to be produced by the patterning recipe, and the design actually patterned by the lithographic apparatus. This may be because the lithographic apparatus, specifically the actuators implementing control settings within the lithographic apparatus, may introduce errors to the exposure. By including knowledge of the apparatus into the cost function, these actuator errors may be corrected for. Alternatively and/or additionally to relations between a pattern design and control settings for the apparatus, control characteristics may include information about the current state of the lithographic apparatus (e.g. lens-heating feed-forward, lens feedback, reticle heating, reticle alignment), information about the substrate (e.g. substrate temperature, substrate alignment, and information about external requests from apparatus interacting with the lithographic apparatus (e.g. metrology tools, data analysis tools).

The control characteristics of a lithographic apparatus LA may comprise information on how an exposure recipe (e.g. a pattern design) may be implemented by a lithographic apparatus LA. The information may be related to the lithographic apparatus in general, or may relate to one or more specific actuators that form part of the lithographic apparatus. The control characteristics may for example include information about limitations to control settings that can be implemented by an actuator in the lithographic apparatus.

The control characteristics may comprise one or more boundary conditions for the correction. The boundary conditions may be based on knowledge of limitations of one or more of the actuators implementing control settings in the lithographic apparatus. Limitations on actuators may include for example speed of movement of the actuator/actuator elements, range of movement, direction of movement, cross-talk causing undesired effects, etc. The limitations may be a result of there being a short time available between subsequent exposures, relative to speed of the actuators. By including knowledge of the limitations to the actuators in the cost function, they can be taken into account when determining a correction, for example by applying them as boundary conditions. An advantage of doing this is that the effect of limitations can be accounted for by the cost function over a plurality of fields.

The control data may be or may comprise control settings for one or more actuators of the lithographic apparatus LA, or may comprise other types of data from which control settings may be determined. Examples of control data include a routing order for a plurality of fields to be exposed across a substrate, a setpoint for lens manipulators, settings for power, pulse duration, or other radiation properties of radiation provided by a radiation source.

The reduction of a patterning error may be seen as an improvement in the adherence of actual parameter values to the intended values of that parameter in the pattern design. The extent to which actual and designed parameter values correspond may be seen as a measure of performance of the patterning process. As a result, such parameters may be referred to as performance parameters. Examples of performance parameters include overlay, alignment, levelling, critical dimension, focus, dose, etc.

The error to be identified and reduced by the cost function may be a residual error. A residual error may be understood as an error that cannot be described by the model. Residual errors may be distinguished from control errors, which are errors that can be described by a control model for determining control settings, but cannot be actuated. Residual errors may remain after the control settings for a lithographic apparatus for exposing a pattern design have been determined, for example by the control model. As a result, the residual may be identified and corrected for based on metrology data, or other data associated with previously exposed substrates.

The cost function may have knowledge of the patterning process, so that it is able to analyse the received parameter data and identify one or more errors on the substrate. The cost function may further have knowledge of the lithographic apparatus as described above, so that it is able to determine how the identified errors on a previously exposed substrate may be corrected, and how these corrections may be implemented. To do this, the cost function may determine one or more corrections to the patterning recipe. The cost function may provide an output indicative of the determined corrections. This may for example be in the form of corrections to a patterning recipe, control settings to be provided to a lithographic apparatus LA, or any other form of control data from which updated control settings for the lithographic apparatus LA may be determined.

Next to knowledge about the patterning process and lithographic apparatus, the cost function may also have knowledge about (and may be based on) the characteristics of the applications and processes used to determine the patterning recipe and/or control settings based on a desired process design. This may be advantageous, as it allows the cost function to take into account and correct for errors introduced by this part of the patterning process.

A cost function may determine control data to minimise the error for a next exposure of a pattern by a lithographic apparatus across a plurality of fields. The error to be minimized may for example be a residual of a performance parameter across a plurality of fields. There are many different ways to define a minimization of error. For example, an average error across each of the plurality of fields may be minimized giving the same importance weight to each of the fields. In another example, different fields may be given different weights for determination of an error reduction across the plurality of fields. This may be done to prioritise error reduction in fields with smaller critical dimensions/more stringent performance requirements. In some instances, edge fields may be given a lower importance compared to inner fields, due to the lower amount of structures present in edge fields and/or the higher likelihood of errors present at the edge of the substrate. This may result in fields on the edge of the edge of the substrate being sacrificed as non-yielding fields. Alternatively, in cases where edge field error corrections are considered possible to implement, fields on the edge of a substrate may be given a higher importance compared to inner fields, as the tolerance for errors in inner fields may be slightly higher. The decision on whether or not to sacrifice edge fields may be taken not just for an edge field, but for a die comprised in the edge field. A field may comprise a plurality of dies, wherein separate dies may form part of the separate product structures. The skilled person will appreciate that the different ways of implementing the error minimization all fall within the scope of the present disclosure, given the minimization is performed over a plurality of fields on the substrate.

The output provided by the cost function comprises a correction to be implemented in the form of changes to control settings for the lithographic apparatus LA. Corrections may be expressed in relation to a performance parameter (e.g. in relation to required changes in overlay, alignment, focus, etc.) Corrections may also be expressed in relation to control data associated with the lithographic apparatus. Control data may comprise control settings for the lithographic apparatus, that is to say, control settings that can be provided to one or more actuators of the lithographic apparatus directly. Control data may also comprise data that requires some additional processing to form control settings to be provided to one or more actuators. Such processing may be performed by the lithographic apparatus itself, or by a processing application external to the lithographic apparatus.

An advantage of determining corrections in the form of control settings for one or more actuators of a lithographic apparatus, is that it may enable the cost function to correct for errors introduced by the actuator(s). This error may be considered a residual of the one or more actuators. Specifically, if there is a difference between the control settings corresponding to a pattern design, and the exposed pattern due to errors introduced by an actuator, the cost function can address these issues.

In a specific example, an actuator may be limited in the amount of change that can be applied to a control setting between two subsequent exposures. The range of a setting that can be achieved by an actuator for a particular field may therefore depend on the setting applied for that actuator in the previously exposed field. In cases where a cost function determines a control setting for each field separately, the range over which the control setting can be implemented is unknown when no information from the previous field is used. The cost function may address this issue for example by setting the same range (boundary conditions) for each field. However, this results in a more stringent limitation than is necessary, and may lead to correction potential going unused. Said differently, the optimal determined correction may fall outside the imposed stricter boundary conditions, even though the optimal determined correction is in reality achievable by the actuator given the actual limitations.

In order for the cost function to provide an output with a correction taking into account control settings for one or more actuators, knowledge about these actuators may be included in the control characteristics of the lithographic apparatus on which the cost function is based. This information may be used in the cost function in the form of a separate term to by minimised. An example cost function not taking into account actuator settings may be:

$${arg min}_{{x}_{l}} {‖ {C}_{l} {x}_{l} - {x}_{0} ‖}_{2}^{2} , {A}_{l} {x}_{l} \leq {b}_{l}$$

Wherein xₗ may be the values to be determined by the cost function, xo the intended design values, and bₗ boundary conditions imposed by the lithographic system. Cₗ and Aₗ may be analogous matrices of a model linking a pattern design to recipe settings. This model may for example form part of computer system CL described above. The error that may be determined using the example cost function above may be seen as a fitting error by computer system CL. In general, Cₗ and Aₗ may describe the actuation capabilities of the lithographic apparatus LA in a partial manner. That is to say, it is possible that Cₗ and Aₗ do not contain all information on the actuation capabilities of the lithographic apparatus LA.

More detailed knowledge about actuators (than used in the cost function above) may be implemented in the form of an additional term which may be used to estimate an expected actuation error to be made by one or more actuators of the lithographic apparatus LA.

$${arg min}_{{x}_{l} {x}_{t}} ( {‖ {C}_{l} {x}_{l} - {x}_{0} ‖}_{2}^{2} + a {‖ {C}_{l}^{*} {x}_{l} - {C}_{t} {x}_{t} ‖}_{∞}^{2} ) , {A}_{{l}^{x} l} \leq {b}_{l} , {A}_{t} {x}_{t} \leq {b}_{t}$$

Wherein Cₗ*, Cₗ, and Aₜ may be analogous matrices of a model linking pattern design to lithographic apparatus control. Cₗ* and Cₗ use the same basis but may in general differ with respect to the sampled positions. Cₜ*, Aₜ may represent properties of (actuators of) the lithographic apparatus. Cₜ, Aₜ may use a different basis than Cₗ*, Cₗ. Cₜ, Aₜ may be used in the lithographic apparatus LA. Cₗ*, Cₗ may be used to transmit information between the computer system CL and the lithographic apparatus LA. xₗ may be the values corresponding to control data to be determined by the cost function. xₜ may be the optimal actuator setting corresponding to xₗ. bₗ, bₜ may be the boundary conditions associated with the computer system CL and lithographic apparatus LA, respectively. The skilled person will appreciate that the above is an example of a cost function, and that other forms of cost function for reducing an error between a designed pattern and exposed pattern may be used.

The cost functions described above may use a single cost reduction and/or minimization step for a plurality of fields on a substrate, for example all fields on a substrate. As mentioned above, the determination of correction for multiple fields as part of the same calculation or set of calculations may lead to the cost function having a high computational cost. This issue may be addressed by using large scale optical solver as a cost function. The large scale optimization solver may for example be a quadratic solver using sparse linear algebra. The matrices the Cₗ, Aₗ, Cₗ*, Aₛ described above may be a sparse representation of the models used to determine the control settings. The sparse nature of the cost function may make it possible and practical to obtain a solution within the timing constraints in which the calculations of the correction for the substrate to be exposed should be determined. Due to the sparse nature of the matrices, the Hessian of the optimisation problem will be sparse, and the constraints on the correction will be sparse. This may lead to a relatively low computational cost for a given amount of fields.

The cost function may be able to determine control data for a lithographic apparatus LA, wherein the control data is associated with the degrees of freedom of control of the apparatus. Said otherwise, the cost function may be able to determine control values for one or more parameters associated with a lithographic exposure. An example of a degree of freedom/parameter which a cost function is able to set is a setpoint for a lens manipulator, as described in more detail below.

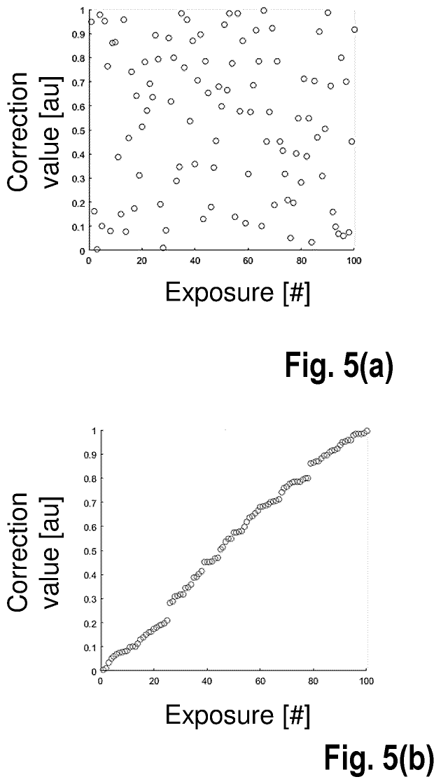

Another degree of freedom which may be available to the cost function will be described in relation to FIGS. 5(a) and 5(b), namely the routing sequence, that is to say the order in which fields on a substrate are exposed. As mentioned above, a lithographic exposure may comprise a plurality of exposure fields, wherein the apparatus exposes the fields one by one. In high volume manufacturing uses of a lithographic apparatus, reducing overall exposure time for a substrate may often be a main aim. The routing sequence may be determined to expose as many fields as possible in a given time. This may be achieved for example be limiting the amount of distance the stage (wafer table WT) on which the substrate is placed needs to travel during the exposure of the substrate. The lithographic apparatus may be a scanner, wherein the scan direction sequence may be in a vertical direction (e.g. scanning up-down-up). Hence movements of the substrate by the stage may be in a horizontal direction perpendicular to the scanning direction. The fields along a horizontal direction may be referred to as rows. In applications in which exposure time a key consideration, the apparatus may expose neighbouring fields sequentially. The routing sequence may follow fields with neighbouring positions across the substrate.

A routing order following a typical exposure sequence is shown in FIG. 5(a). The exposure sequence may be an exposure meander. In an exposure meander, subsequent fields to be exposed may be neighbouring on the same row. Once fields on a row have been exposed, the sequence may move to a next row. The next row may be neighbouring to the row that was just exposed, or may be a row elsewhere on the substrate. The exposure fields are depicted on x-axis in routing order. A representation of a correction value for that field in arbitrary units is shown on the y-axis. As can be seen on the figure there is no clear relationship between the correction values for neighbouring fields (neighbouring positions on the x-axis). This may lead to the determined changes in corrections not being possible to be implemented due to boundary conditions resulting from limitations imposed by the lithographic apparatus. As a result, the corrections may differ from a preferred setting to take into account the limitations from the actuators. In some instances the high volume manufacturing may be too important a consideration to the routing sequence as a degree of freedom. However, in some other instances, for example where the volume/speed of manufacturing is less critical, the routing sequence may be provided as a degree of freedom.

FIG. 5(b) depicts a graph showing a schematic representation where the routing order in which fields on the substrate are exposed has been organized based on the determined correction value. This means that neighbouring fields on the substrate may not necessarily be exposed immediately subsequent to each other. Compared to setup in which neighbouring fields are exposed in series, this routing sequence may lead to more time being needed between subsequent exposures, to give the wafer table time to reposition the substrate. An advantage of this setup may be that subsequently exposed fields have small changes in correction between them, meaning it is unlikely the boundary conditions would impede the desired control settings to be applied. The small changes between subsequently exposed fields may fall within the limits of the actuators of the lithographic apparatus LA. As a result, the corrections determined to be applied by the cost function may be better. This approach preferring correction quality over manufacturing volume may for example be preferred in research and development uses of the apparatus, or for patterning processes working very close to the finest resolution limit of the lithographic apparatus LA.

The routing sequence of FIG. 5(b) may have been determined by the cost function to minimize changes in corrections between subsequent exposures without taking into account the position of subsequent fields relative to each other. This is in contrast to FIG. 5(a), where the relative position of subsequent fields is considered regardless of differences in correction to be applied. It is possible for the cost function to determine a routing sequence finding a balance between differences in correction to be applied, and position on the substrate. For example, edge fields, that is to say fields at the edge of the wafer, may generally require stronger corrections compared to inner fields. A cost function may for example determine to expose all edge fields together (large expected corrections), potentially ordering them so that similar corrections are exposed subsequently. Inner fields (small expected corrections) may be exposed before or after the edge fields.

Next to a routing sequence, the amount of preparation time may be provided as a parameter/degree of freedom, that is to say, the amount of time available to the lithographic apparatus to implement the corrections for the next exposure. In between two exposures by a lithographic apparatus, a correction to the exposure settings may be determined. The amount of time required to implement a particular correction may depend on the speed of the actuator(s) implementing the correction. It may also depend on the difference between the current setpoint of an actuator and the setpoint associated to the correction to be implemented. This correction may for example be determined by a cost function as described above. The amount of time it takes to implement a correction may be known to the cost function, and may be taken into account by the cost function in the form of boundary conditions applied to the corrections to be determined. Corrections to multiple control data values may be implemented to correct for residual errors in an exposure process. Examples of such control data values may include for example wafer table position, reticle stage position, lens actuator setpoint, radiation properties (wavelength, power, pulse duration), etc.

The amount of time available to a lithographic apparatus to implement a correction, also referred to as the preparation time, may be determined by the time between two exposures by the lithographic apparatus. In a known implementation, the available preparation time may be as low as possible, in order to maximize the amount of exposures performed by the lithographic apparatus. This may for example be the case in high volume manufacturing applications and uses of a lithographic apparatus. When the time between exposures is kept low, the time available to implement a correction is also kept low. This may result in stringent boundary conditions being applied by the cost function. This may mean the quality of the determined correction may be reduced as a result of limitations to the range of corrections that can be implemented.

In some implementations the preparation time may be provided as a degree of freedom. Increasing the preparation time between exposures may be used as a tool to relax the boundary conditions applied by the cost function. The decision to increase the amount of preparation time and by how much may be based on finding a balance between the improvement in correction performance, and the reduction in manufacturing volume by increasing time between exposures. The benefits resulting from improved corrections may depend on the specific design and pattering requirements of the pattern to be exposed. The advantage of an increased available preparation time may therefore be assessed for each pattern design individually. The advantage may also be assessed for a substrate layer as a whole.

Although quality of an exposed pattern may be considered on a continuous scale, for example as a percentage of correspondence between an exposed and designed pattern, it is also possible to make a discrete pass/fail judgement on an exposed pattern quality. That is to say, the quality of an exposed pattern in a die of a field may lead to either a functioning product or portion of a product (OK), or a non-functioning product or portion of a product (NOK). This may also be expressed in terms of OK/NOK residuals, that is to say errors that still allow a field to function (OK) or not (NOK). The boundary between OK and NOK residual values may be referred to as a residual threshold. The residual threshold may represent an upper limit for a residual resulting in a functioning exposure patterned on a field. The decision on whether to increase the available preparation time may be based on whether it will lead to an increase in the proportion of fields that are exposed with OK residuals, and/or the size of the increase in NOK to OK field exposures.

It is therefore proposed to provide an interface which may determine the highest allowed residual to be present in the exposed pattern to still achieve an OK residual on a field exposure. The highest allowed residual may be the same for all fields on the substrate, or may be determined separately for each field. Based on the maximum allowed residual, an assessment may be made on whether an increased preparation time should be set.

In an example implementation, a layer on a substrate may be divided into a plurality of regions, wherein each region represents an individual product unit on that layer, also referred to as a die. In many cases, an exposure field may comprise multiple regions (dies). However, in some applications, it is possible that a single product is spread out over multiple exposure fields stitched together, in which case a region may span across multiple exposure fields. The same division into regions may be present across at least some of the layers on a substrate. A product may consist of the plurality of regions across each of the plurality of layers on the final patterned substrate.

The decision on whether to increase preparation time for an exposure field may be made based on the increase in regions with OK residuals in the field. This assessment based on OK/NOK regions instead of fields may result in preparation time decisions providing a higher yield of OK products (dies) compared to decisions based on exposure fields themselves. This may allow a more practical decision on preparation time, based on an increase in functioning final product yield. Setting preparation time based on OK residual threshold for regions may be significant for example if some regions in a field have a lower residual threshold compared to other fields. For example, some regions may have a lower error tolerance due to strict patterning requirements. This may affect the required preparation time for the exposure field comprising that region to be higher in order to pass the OK threshold. Next to a region, an OK/NOK residual assessment may also be made over a plurality of layers on a substrate. For example, the assessment may be made for each layer on a finished substrate, wherein the decision on whether to increase the preparation time is based on the increase in OK final products achieved on the finalised exposed substrate. The preparation time determination based on number of products passing an OK residual threshold may also be seen as assessing the yield of the patterning process.

The amount of regions that achieve an OK residual may be seen as a key performance indicator for the lithographic patterning process. Alternatively or additionally to assessment of regions across a single layer, a final product yield may be used. As mentioned above, the yield may be assessed for individual layers on a substrate (i.e. regions in a single layer, or for multiple layers forming a finalised product (regions in different layers forming part of the same final product). The allowed preparation time may be adjusted separately for the exposure of one or more layers on a substrate in order to increase the die yield in the layer and/or the overall product yield on that substrate.

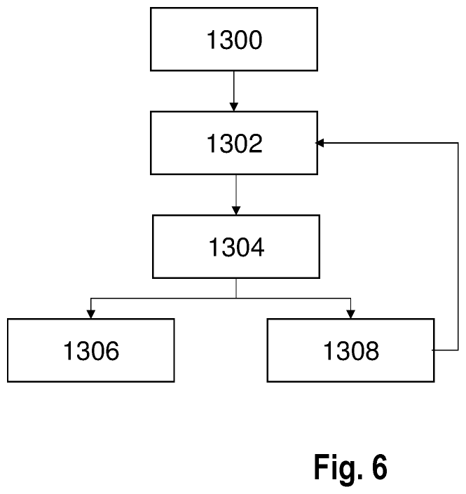

The following method as depicted in FIG. 6 may be used to determine whether to allow additional preparation time. In a first step 1300, the residual is calculated using the current available preparation time. In a second step 1302, the residual is calculated for an increased preparation time. In a third step 1304, it may be assessed whether the residual achieved for the increased preparation time leads to an increase in OK residuals for field, region, and/or product performance. The increase (or lack thereof) in OK residuals for field, region, and/or product performance for the increased preparation time compared to the current preparation time may be assessed to determine whether the increased preparation time should be used. In some implementations, the preparation time may be set to the increased preparation time 1306. In other implementations, further tests may be performed by determining 1308 a different increase in preparation time, and repeating steps 1302 and 1304 for this different increase in time.

In an example implementation, the first increased preparation time chosen in step 1302 may be a maximum allowable preparation time. An iterative process may be used to test several preparation times 1308 lower than the maximum allowable preparation time. The effects of the different preparation times to OK-residual performance may be compared to select a preferred increased preparation time. This iterative process may for example be performed by gradually decreasing the available preparation time from the maximum allowable duration. This further assessment may be used to find a lowest (optimised) preparation time for which an increase in OK fields, regions, and/or product yields is achieved. The maximum allowable preparation time may be determined based on the delays to an exposure process that are deemed acceptable for an application.

As mentioned above, an increase in preparation time may lead to an improved correction being determined for the exposure. The increased preparation time may also be associated with a performance penalty in the form of reduced amount of exposures performed in a given time. Furthermore, an increased preparation time results in an increased separation in time between the exposures of subsequent layers on a substrate. This may have an impact on performance parameters of the exposure, for example on the overlay between those layers. When known in advance, the increased preparation time between different substrates does not affect overlay. However, if an increase in preparation time is unexpected, the lithographic apparatus may have to delay operation of a subsequent exposure unexpectedly (e.g. position of stages and lens setpoint). This may affect overlay performance of the lithographic apparatus. The specific effects of increased preparation time on different performance parameters of the patterned substrates may not always be known in detail.

The method of determining the optimised preparation time may in itself take time, during which exposures may be further delayed if they are performed using the computer system CL and/or lithographic apparatus used for the exposure itself. This delay may be avoided by providing a model associated with the computer system CL and/or lithographic apparatus LA, which may be used to calculate the preparation times in advance of the actual exposure being performed. The model may be based on data/knowledge of the lithographic apparatus LA. The model may comprise a copy of the cost function. The model may comprise a digital copy of the lithographic apparatus functionality, for simulating the lithographic apparatus. This may enable the model to determine how a particular preparation time would affect the amount of fields, regions, and/or products exposed with residuals below the OK threshold. Knowledge of the optimised preparation times to be provided to the patterning process, may be provided to the cost function, and implemented during the exposure of the substrate. The boundary conditions implemented by the cost function may be amended to allow the cost function to determine corrections according to the appropriate timings.

In some implementations, the same preparation time may be provided for exposure of each field and/or layer on the substrate. This may be to provide a similar level of cost function performance, so that the quality of the determined correction may be similar for the different layers on the substrate. In some implementations, different preparation times may be provided for different fields and/or layers on the substrate. The different preparation times may reflect different correction requirements for different layers to reach the OK residual threshold.

When determining a preparation time based on substrate yield, the yield may be determined based on the amount of working products on a finalized substrate, or on exposure fields and/or regions on one or more substrate layers. The yield threshold, that is to say the smallest acceptable yield targeted based on preparation time settings, may be the same for each field, region, and/or layer on the substrate. In other instances, different fields, regions, and/or layers on the substrate may be allocated different yield thresholds. This may for example be to prioritise areas on a substrate comprising patterns considered to have a higher importance.

In an example situation, the preparation time required to implement control settings between exposures of a first field and a second field may be comfortably within the available preparation time determined for that exposure. However, the time required to implement control settings between exposure of the second field and a third field may be higher than the available preparation time. As a result, the third field may be exposed with an NOK residual. By determining individual preparation times for separate fields, a portion of the preparation time not required for exposure of the second field may be allocated for exposure of the third field. This could increase the overall performance of the exposure on the substrate without increasing the total preparation time.

This disclosure will now discuss an example of an actuator for which control data may be determined. The control data may relate to a lens in the lithographic apparatus, and may be configured to apply a determined correction to improve performance of control of a lens in a lithographic apparatus. The control data may be used to determine a setpoint of a plurality of lens manipulators configured to apply deformations to a lens in order to control the lens. A setpoint for a plurality of lens manipulators may also be referred to as control settings for the lens. The control data may relate to one or more corrections of errors in the lithographic exposures of one or more fields on a substrate. These corrections may be based on a model linking pattern design to recipe settings, as described above. A lens model may be used to translate the control data into a setpoint for the lens. The lens model may provide the information to determine actuator-specific control settings, that is to say, information about the lens manipulators controlling the lens.

In the paragraphs below, the translation of model settings to actuator-specific control settings is performed by a lens model that is separate from a cost function for determining a correction. However, the functionality of the lens model may in an alternative embodiment be incorporated into a cost function for determining corrections to the exposure pattern.

In an example implementation of determining control data for a lithographic apparatus, identified errors and associated corrections to be applied to a patterned substrate may relate to a parameter affected by a manipulation of a lens controlling radiation performing a lithographic patterning process. Examples of substrate parameters, also referred to as performance parameters, that may be affected by manipulation of a lens include overlay OVL, critical dimension CD (line thickness), alignment AL, levelling LVL, and edge positioning errors EPE. Identified issues in the parameters may for example be associated with a pattern shift, overlay errors, alignment errors, and/or focus errors in the pattern, or a levelling issue on the substrate. It will be understood that these examples are not exhaustive, and other parameters and/or causes of errors may be used and identified. The identified errors as described herein may also be referred to as residuals.

An optical assembly used for controlling and manipulating radiation for exposure of a pattern onto a substrate may comprise a plurality of optical elements, for example lenses, mirrors, etc. An optical element may have tunable properties that offer control over how the optical element interacts with radiation. The optical assembly may for example comprise a lens having a plurality of lens manipulators. A lens manipulator may be a small element present inside the lens, able to apply small corrections to the properties of the lens (e.g. distortion of field images by the lens). The lens manipulators enable control over how radiation passing through the lens is manipulated by the lens. The setting applied to a lens manipulator, also referred to as the setpoint, may determine how the lens manipulator changes the properties of the lens. A lens manipulator may change the properties of a lens by changing its position in the lens. The changes in properties of the lens as a result of adjustment of positions of one or more lens manipulators may in turn adjust how radiation passing through the lens is controlled. The setpoint may determine the position of the lens manipulator to achieve the desired optical effect in the lens.

In order to translate an identified error/correction or determined desired setpoint for a lens, a lens model may be used. The lens model may receive as input a request for a correction of one or more errors identified for a lithographic exposure of a substrate. The lens model may output a setpoint to be applied to the lens and/or a lens manipulator, based on the received input. The substrate may be divided into a plurality of exposure fields, also referred to as fields. Fields on a substrate may be exposed separately during a lithographic exposure, for example one by one. Separate exposure settings may be applied for separate fields. The lens may for example be used to expose different fields on a substrate in series. An exposure field may therefore be said to have previous and subsequent fields, which are fields exposed before and after that field, respectively. Previous and subsequent fields may also be referred to as preceding and succeeding fields in a series of field exposures. Previous and subsequent fields in a series may be neighbouring fields on the substrate.

The request may provide different setpoints for different fields to be exposed, so that different corrections may be applied for different fields. A lens model may receive as input a request relating to error corrections for a plurality of fields to be exposed sequentially. The request for each field may be based on parameter data for that field. For example, each field on a substrate may comprise one or more metrology targets, which may be measured by a metrology tool MT to determine properties of the pattern exposed on that field. The metrology target may for example be an overlay metrology target. Metrology data may be based on measurements of features other than metrology targets, for example on measurements of product features. Alternatively or additionally, the parameter data may comprise simulation data for one or more fields.

The lens model may be used during operation of the lithographic apparatus LA. Parameter data related to one or more previous exposures performed by the apparatus may be provided to the lens model, to update the setpoint and to apply corrections identified based on previous exposures. To avoid delays to the lithographic exposure process, it may be desirable to limit the amount of computational time needed by the model. The lens model may therefore have certain limitations applied to it to reduce its computational cost. This may also lead to suboptimal performance of the lens model and/or make the lens model less flexible or adaptable. The lens model may for example be designed to calculate settings for fields on a substrate without taking into account setpoints for previous and/or subsequent fields exposed using the lens. The lens model may also assume that all fields on a substrate have the same shape, for example a rectangular shape. As a result, the lens model may be designed to receive a request for a field with a rectangular or other predetermined shape, and may not be able to process inputs with a different shape. This may pose an issue for fields on the edge of a substrate, which are typically not rectangular due to the common circular disk shape of a substrate.

In order to provide a request for an edge field of a substrate to a lens model, the metrology data may only be available for a portion of the expected field shape. The portion of an edge field of a substrate that is taken up by the substrate may be referred to as a partial field. An extrapolation of parameter data available for the portion of the expected field shape not filled by the substrate may be used to create a request fitting a field of the expected shape, e.g. a rectangular shape. The extrapolation may for example be a polynomial extrapolation, wherein the extrapolation is based on the metrology data as input.

Receiving an extrapolated request for an edge field as an input, the lens model may determine a setpoint to be applied by a lens for exposing the field of the substrate. The extrapolated portion of the field represents a virtual portion of the request, as it does not correspond to a substrate exposure. Therefore, the quality of the correction applied by the setpoint to this virtual portion does not matter, as it does not correspond to an area on the substrate. However, a lens model that has been designed to be computationally faster, may be designed to process each input field in the same way. As a result, the lens model may treat each input as part of the same request

The lens model may not be able to distinguish between the virtual portion of the request and the portion of the request representing the partial field. The lens model will treat the virtual portion and partial field portions of the request the same. The lens model will give equal value to the partial field portion and virtual portion of the request. The setpoint may not be able to fully fit to the correction included in the request. The lens model may try to find a best fit to the entire request, fitting to both the partial field and virtual portions of the request. However, fitting to the virtual portion of the request provides no real-term benefits to the quality of the corrections applied by the setpoint. Fitting to an extrapolated field may even result in a setpoint leading to an exposure with worse errors than before the corrections were applied. The methods and apparatus described herein aim to provide an improved requests for a lens model to determine setpoint for a lens.

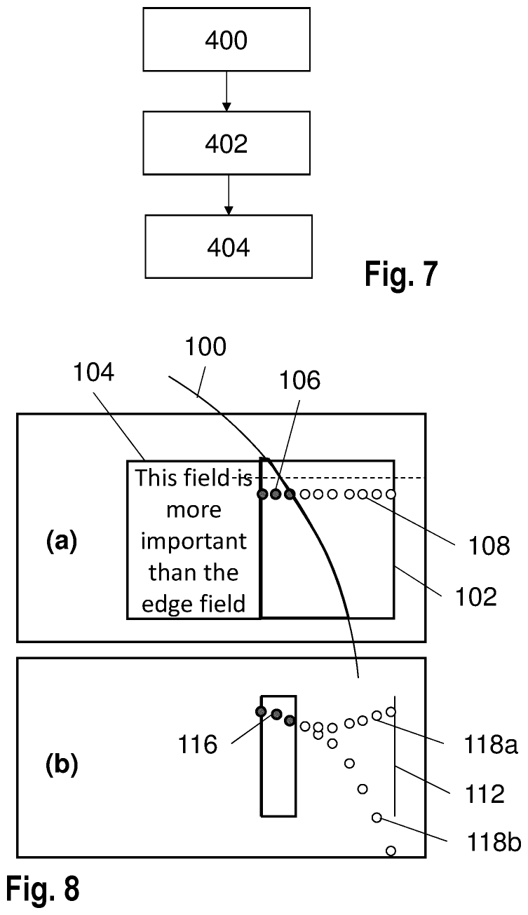

FIG. 7 depicts a flowchart comprising steps in a method for determining an input to a lens model. The input may be determined as a request for providing to a lens model. The lens model may determine a setpoint for manipulation of a lens of a lithographic apparatus for at least one of a plurality of fields of a substrate. The methods described herein may be performed by one or more processors executing a series of instructions saved in a storage medium. The processors may be provided separate from the lithographic apparatus LA and/or a metrology tool MT.

In step 400, parameter data is received for the at least one field on the substrate. The parameter data relates to one or more parameters of the substrate within the at least one field. The one or more parameters may be at least partially sensitive to manipulation of the lens as part of an exposure performed by the lithographic apparatus. In step 402, the method receives lens model data relating to the lens. The lens model data may comprise a copy of the lens model, and/or may comprise other data characterizing the lens model. In step 404 the method determines the request based on the received parameter data and lens model data. Once determined, the request may be provided as input to a lens model. The lens model may then determine a setpoint based on the received request. The lens model may determine a setpoint per field. The setpoint may be applied to a lithographic apparatus LA for a lithographic exposure for patterning a structure onto a substrate. The structure to be patterned may have the same intended design as the structure for which the parameter data was received.

An advantage of the method as depicted in FIG. 7 may be that an input can be determined that takes into account specifics of the lens model. The input may be determined at least in part by a cost function, wherein the lens model may form part of the control characteristics on which the cost function is based. The request to be input may be determined offline, that is to say, separate from the lithographic apparatus and lens model. An advantage of determining an input offline, for example using one or more offline calculations may be that more computing time is available, allowing more time consuming (e.g. complex) calculations to be used for determining the input. This may increase the quality of the resulting input. The request may for example be determined to optimize the setpoint based on the characteristics of the lens model. The lens model data may for example be used to determine an extrapolation leading to a setpoint determination that provides a good fit for a partial field. The lens model data may alternatively or additionally be used to take into account setpoints for one or more previous and/or subsequent fields, to be exposed before and/or after the field. Ways in which the request may be optimised based on a combination of metrology data and lens model data will be set out in more detail below.

The parameter data may comprise one or both of metrology data and simulated data. The parameter data may be obtained for one or more previous lithographically patterned substrates. The parameter data may comprise data that identifies an error in a parameter of a structure patterned within the at least one field, using the lithographic apparatus. The parameter data may for example comprise a fingerprint for one or more parameters, wherein a fingerprint may comprise data associated with one or more of a pattern shift, an overlay error, an alignment error, and/or a focus error.

The at least one field may comprise a partial field. The partial field may be an edge field on the substrate, as depicted in FIG. 8. FIG. 8(a), shows a portion of a substrate 100, indicating a plurality of fields. The fields may all have the same size. The image depicts an edge field 102, wherein the edge field is only partially filled by the substrate 100. An inner field 104 is also illustrated in which the substrate 100 covers the entire field. In the edge field, parameter data may be provided at locations 106 that are covered by the substrate. The locations 108 in the portion of the field not covered by the substrate 100 do not have parameter data available. However, the lens model may expect the request to provide input for these points. An extrapolation may be determined to provide values for the locations 108 in the portion of the edge field 102 not covered by substrate 100. FIG. 8(b) shows a schematic representation of extrapolated data, based on parameter data. The extrapolated data may be used to create requests 112, which may be referred to as extrapolated requests 112. The extrapolated requests 112 may each be in the required format to be input to the lens model. Each of the extrapolated requests comprises the parameter data 116 available for the partial field covered by the substrate. The requests 112 also depict a plurality of different possible extrapolations 118a, 118b for the locations not covered by substrate 100. The extrapolations 118a, 118b may be based on the parameter data 116. The parameter data 116 may comprise parameter data, such as metrology data, relating to locations inside the partial field. Determining the request may comprise optimising the request to apply a correction to the one or more parameters. The correction may be identified by the parameter data relating to the locations within the partial field. The correction may be a correction of an error identified in the parameter data. This may for example involve determining which of the plurality of possible extrapolations 118a, 118b provides the best setpoint fit to correct at the locations 106 of the partial field.

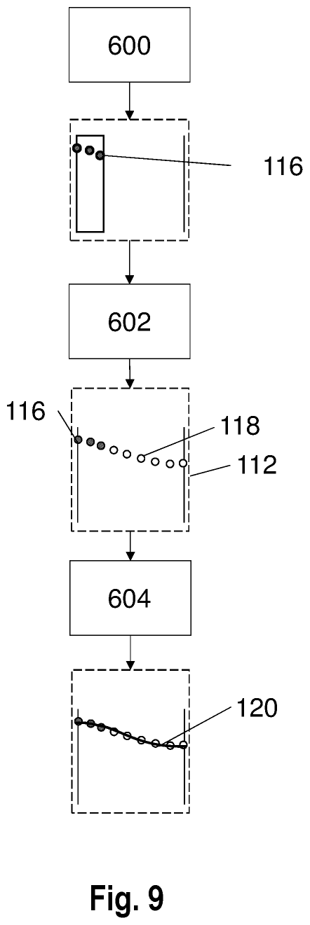

The steps to optimize the request may be performed using a first lens model based on the lens model data. The first lens model may comprise a cost function as described above. FIG. 9 depicts a schematic representation of steps in a method for determining a setpoint 120 for manipulation of a lens, and entities that perform them. A metrology tool MT and/or simulation tool 600 may provide parameter data 116 relating to one or more parameters of the substrate. The parameter data may be provided to a first lens model 602. The first lens model 602 may be determined based on the lens model data. The first lens model data may further be determined based on knowledge of the lithographic apparatus LA. The first lens model 602 may determine a setpoint. The first lens model 602 may optimize the setpoint inside the partial field. To optimize a setpoint inside the partial field, the first lens model 602 may determine an initial setpoint based on the parameter data 116. The initial setpoint may be determined for the portion of the field covered by the partial field. The first lens model 602 may then evaluate the initial setpoint and determine a setpoint across a full field. The setpoint for the full field may comprise the initial setpoint for the partial field. The first lens model 602 may also determine a request 112 corresponding to the determined setpoint. The request 112 may also be referred to as an extrapolated request, due to the extrapolation applied to obtain extrapolated data 118 of the request. The request 112 may also be referred to as an optimized request or and optimized extrapolated request, due to the optimization step applied by the first lens model 602 to determine the request. The request 112 may be provided as input to a lens model 604 for a lithographic apparatus LA. The lens model may determine a setpoint 120 for manipulation of the lens. The determined setpoint 120 may be provided and implemented to the lens of the lithographic apparatus LA. FIG. 9 shows a comparison of the correction obtained by applying the setpoint 120 and the request 112. The quality of the request 112 may affect how well the corrections applied by the setpoint 120 address the errors identified by the parameter data 116. The quality of the fit of the setpoint 120 to the request may also affect how well the corrections applied by the setpoint 120 address the errors identified by the parameter data 116.

The first lens model 602 may be based on the lens model data. The first lens model may combine the lens model data with the parameter data 116 to determine the extrapolated request 112. The first lens model 602 may comprise a copy of the lens model. The first lens model may alternatively or additionally use knowledge of the structure and/or function of the lens model, provided by the lens model data, to determine or estimate the effect of the lens model on a request. The first lens model 602 may be applied offline, that is to say, separately from the running of the lithographic apparatus LA and the manipulation of the lens. For example, a first lens model may be used for determining a request before starting a lithographic exposure. This may provide the first lens model 602 with additional computation time to determine setpoints, compared to a situation where the lens model 604 receives and processes inputs during a lithographic exposure. This allows the first lens model 602 to be more computationally complex than the lens model 604.

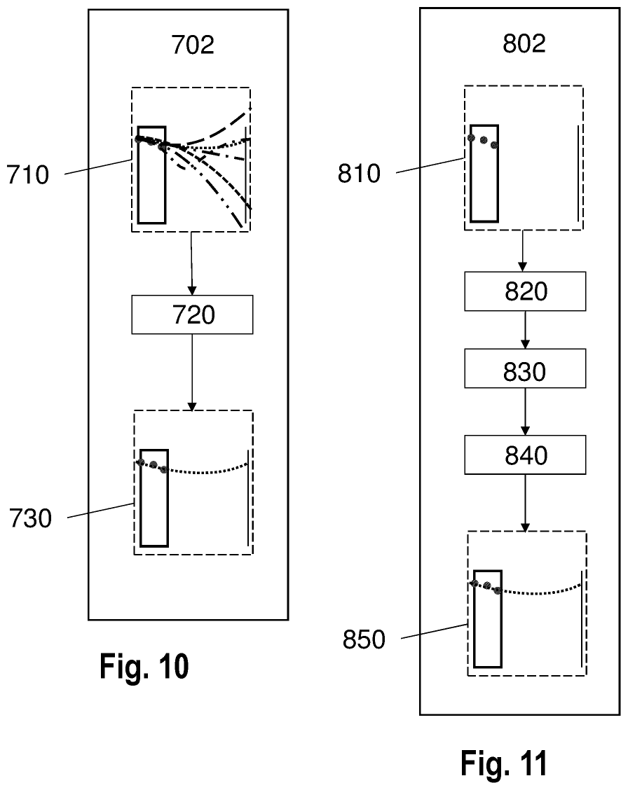

FIG. 10 depicts an example first lens model 702, which may be based on a brute force method. The first lens model 702 may determine a plurality of extrapolated requests 710 based on the parameter data 116 for a partial field 102. The extrapolations may cover the portion of the field outside of the partial field. The plurality of extrapolated requests 710 may be referred to as provisional inputs, or provisional requests. The lens model data may comprise a copy 720 of the lens model. Each of the determined provisional requests 710 may be provided as input to the copy of the lens model 720. The copy of the lens model 720 may determine a setpoint for each of the extrapolated requests 710. The first lens model 702 may then determine the preferred setpoint from the plurality of determined setpoints. Determining the preferred setpoint may for example comprise determining the setpoint which most accurately implements corrections in the partial field covered by the substrate 100. The provisional request that applies a correction that is closest to the correction identified from the parameter data 116 may be selected. The provisional request providing the preferred setpoint may be selected as the optimised request 730. This optimised request 730 may be provided to the lens model of the lithographic apparatus LA. Determining the preferred setpoint may also take into account the impact of the setpoint associated with each of the provisional requests on a subsequent field to be exposed.

FIG. 11 depicts a second example implementation of steps performed by a first lens model 802. The first lens model may comprise a partial field aware lens model 820 for determining a setpoint based for an edge field. A partial field aware model 820 may be based on the lens model. A partial field aware lens model 820 may take into account that it does not need to optimize that part of the field outside of the substrate. The partial field aware model 820 may be able to receive inputs with a partial field shape 810, for example having less parameter data 116. The partial field aware model 820 may be able to determine a setpoint 830 for the lens based on the partial field input 810, without needing an extrapolation of data into the remaining portion of the field. An advantage of this approach may be that the determined setpoint 830 may be optimised for the partial field.

The determined setpoint 830 may be based on parameter data 116, without being based on extrapolated data. The setpoint 830 has not been fitted to extrapolated values in a virtual portion of the field. The first lens model 802 may further evaluate 840 the optical effects on the full field of the requested setpoint values outside of the partial field that are a result of optimizing the request for partial field covering the substrate. The setpoint for the full field may be used to determine a corresponding request that has a suitable format to be input to the lens model. This may involve evaluating the effects of the setpoint 830 over the full field, and using the resulting effects as the request for input to the lens model. The first lens model 802 may determine this as an extrapolated request 850 that when input to the lens model, outputs a setpoint matching the optimised setpoint 830 determined by the partial field aware model 820. In some instances the extrapolated request 850 may lead to an output matching the optimised setpoint 830. In other instances, the extrapolated request 850 may lead to an output closely resembling the optimized setpoint 830. The determined extrapolated request 850 may be provided as input to the lens model of the lithographic apparatus LA. A partial field aware lens model 820 may use information about the exposure route of fields on a substrate. This information may be provided as part of the lens model data.

A plurality of setpoints for manipulation of a lens may be determined for a plurality of fields. A different setpoint may be determined for each field on a substrate. The fields may be exposed in series by the lithographic apparatus. Subsequent fields may be exposed in quick succession, meaning the time available to adjust the setpoint between subsequent field exposures may be limited. Furthermore, the dynamic properties for the manipulation of the lens may also be limited. For example, the speed and range by which lens manipulators are able to move across the lens may be limited. As a result, it may not be possible to implement large variations between subsequent setpoints. Information about the dynamic properties of the lens may be provided as part of the lens model data. This information may also be referred to as dynamic data. The dynamic data may be used by a cost function to set boundary conditions. These boundary conditions may represent limits to the type of correction that can be implemented by the lens. If a variation between two or more neighbouring setpoints is large, the accuracy by which the lens implements the setpoint may be reduced. This may in turn reduce the accuracy of the corrections applied by the manipulation of the lens, which may negatively affect the quality of the resulting pattern. In order to address this challenge, the request determined for one field, may take into account the requests determined for one or more neighbouring fields.

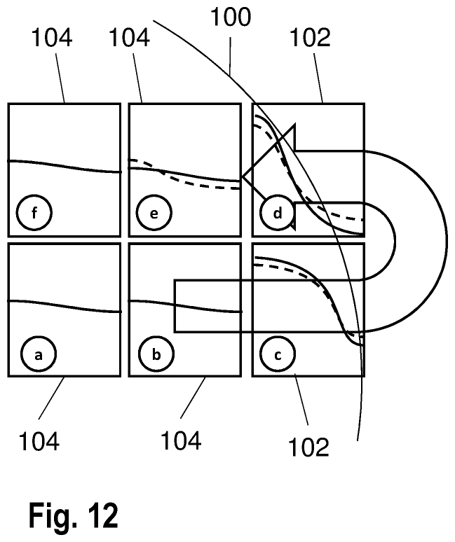

FIG. 12 depicts a schematic representation of a portion of a substrate 100. The portion comprises a plurality of edge fields 102 and inner fields 104. An arrow indicates an order (alphabetical order from a to f) in which the fields are programmed to be exposed by the lithographic apparatus LA. A setpoint is determined for each of the fields. The determined setpoint is depicted in FIG. 12 as a solid line. If setpoints for different fields are determined independently from each other, they may have large variations between them. As shown in FIG. 12, the setpoints determined for the edge fields 102 vary strongly from the setpoints determined for the inner fields 104. The system for manipulating the lens may not be able to apply such strong variations for consecutive fields.

In order to address potential problems with subsequent setpoints not being compatible with each other, a setpoint for a first field may be based on a setpoint for one or more second fields. The one or more second fields may be neighbouring fields. Neighbouring fields may be fields that are programmed to be exposed before and/or after the field. Neighbouring fields may be fields that are adjacent to each other. The lens model data may comprise data to allow setpoints of neighbouring fields to be taken into account. The lens model data may for example comprise dynamic data for the lens. Dynamic data may include information about the speed and range of variations in manipulation that can be applied. This may for example include the speed by which lens manipulators may move. Dynamic data for the lens may be used to determine whether a plurality of setpoints for a plurality of fields can be applied to the lens successfully. If one or more of the variations between subsequent setpoints is not suitable to be implemented by a lens, adjustments may be made to one or more of the setpoints. In FIG. 12, adjusted setpoints are depicted as a dashed line. For example, in FIG. 12, the setpoints for edge fields 102 (fields c and d), may be adjusted to have a smaller variation compared to the previous field b, and subsequent field e. Adjustments may also be made to inner fields b and e, to accommodate the larger setpoint variation at edge fields c and d.

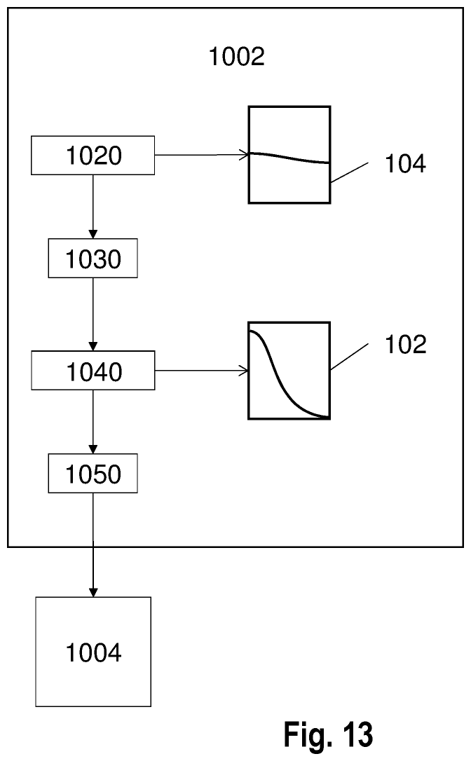

FIG. 13 depicts a schematic representation of steps in a method for determining an input to a lens model wherein a setpoint for a field may be determined based on a setpoint for one or more other fields. A first lens model 1002 may be provided to determine an input for the lens model 1004. The first lens model may determine, using a first module 1020, a setpoint 1030 for one or more inner fields 104. The lens model may use at least a portion of the lens model data available to it to determine a setpoint 1030 for the one or more inner fields 104. The lens model may then provide the determined setpoints 1030 to a second module 1040. The second module may use at least a portion of the lens model data and the determined setpoints 1030 for the one or more inner fields to determine a setpoint for one or more edge fields 102. Based on the lens model data and the setpoints for the inner fields 104, the second module may determine the setpoints for the edge fields 102 that are possible to be applied to the lens. The setpoints 1050 for the inner fields 104 and edge fields may be provided to the lens model 1004 to be applied during a lithographic apparatus LA.

The first lens model 1002 may be provided with information relating to an importance of fields relative to each other. For example, a partial field may have a lower importance than a full field. This may be because the full field has more available area, and may therefore contain more patterned product features. An importance may be allocated based on the design of a pattern to be exposed on the substrate 100. The importance may for example correspond to the amount of structures to be patterned in the field. The importance may additionally or alternatively correspond to a dimension of at least a portion of the structures to be patterned in the field. For example, structures with smaller critical dimensions may be allocated a greater importance due to the more stringent patterning requirements for exposing those structures.

A field may be divided into several regions, wherein different regions may have a different importance allocated to them. The first lens model may use the relative importance to determine a setpoint in a field. For example, a first region within a field may be allocated a higher importance relative to a second region in that field. For example, a region in a field comprising a design of structures with smaller dimensions may be allocated a greater importance compared to a region with structures with bigger dimensions. The first lens model 1002 may prioritise optimising the setpoint for the first region over the second region.

The importance of fields and/or regions in a field on a substrate relative to each other may be provided to a first lens model 1002 as part of the parameter data 116. A first lens model may use the information on relative importance of fields to determine a setpoint. A first lens model 1002 may for example determine an initial setpoint for a plurality of fields. The first lens model 1002 may then use lens model data to determine whether the variations between subsequent fields are possible to be applied to the lens. If the lens manipulation is not able to reliably apply the initial determined variations, the first lens model may use this information to determine one or more adjustments to the initial setpoints. The adjustments may take into account a relative importance of fields and/or regions within a field.

In an example implementation, a first lens model may be used to, in a first step, determine a plurality of setpoints for a plurality of fields. In a further step, the first lens model may use the plurality of setpoints, and dynamic data relating to the lens model manipulation, to determine whether the manipulation of the lens is able to apply the variation between subsequent setpoints. The first lens model may then determine one or more adjustments to the setpoints, to provide updated setpoints. The updated setpoints may be provided as input to the lens model.

As described herein, a first lens model may be used to optimize an input to be provided to a lens model for manipulating the lens. The functions of a first lens model 602, 702, 802, 1002 as described herein may be combined. For example, the first lens model may use extrapolation methods to determine inputs covering a full field for partial fields, and may also use neighbouring fields to determine and/or adjust a setpoint for a field. An exemplary method as described herein may comprise determining an input for a lens model for one or more full fields for the full field based on parameter data for the full field. The method may then determine a input for the lens model or one or more partial fields, for example using the extrapolation methods described above. For the determination of the input for the partial fields, the input for the full fields may be used as a constraint.

Parameter data may relate to errors in a pattern exposed on a substrate. The parameter data may comprise information indicating errors directly. Alternatively or additionally, errors may be determined based on the metrology data. This may for example be done by comparing metrology data to expected values for the metrology data in case of an error-free patterned structure.

The one or more parameters may comprise overlay OVL. The method may provide parameter data for a plurality of parameters, for example including overlay OVL, alignment AL, levelling data LVL, edge placement error data EPE, data relating to focus, etc. The parameter data may comprise metrology data. Metrology data may be obtained by different metrology tools MT. The metrology data may be obtained for structures patterned by the same lithographic apparatus LA as the one for which the lens model request is determined. The parameter data may alternatively or additionally comprise simulated data relating to patterns exposed on a substrate. The simulated data may be based on metrology data. The parameter data may relate to a previous iteration of a lithographic exposure of the same pattern, as the pattern for which the lens model request is being determined. This may allow updating of an exposure process based on data related to one or more previous iterations of the same exposure process. The parameter data may be associated with one or more of a pattern shift, overlay errors, alignment aberrations and/or focus errors.

The lens model data may comprise information about the lens model. The lens model data may comprise a copy of the lens model. The lens model data may comprise dynamic data for the lens. Dynamic data for the lens model may include information on how the lens performance changes based on adjustments the setpoint for the lens. This information may comprise information about for example regarding speed by which a setpoint can be adjusted, or time of exposure.

Further embodiments are disclosed in the list of numbered clauses below:

1. A method for determining control data for a lithographic apparatus, the method comprising:

receiving parameter data associated with a plurality of fields of a substrate;

providing the parameter data as an input to a cost function;

evaluating the cost function extending across the plurality of fields, wherein the cost function is based on control characteristics of the lithographic apparatus, the cost function providing an output comprising a correction configured to reduce a residual of a performance parameter across the plurality of fields of the substrate;

determining the control data based on the output.

2. A method according to clause 1, wherein the control characteristics of the lithographic apparatus comprise one or more boundary conditions for the correction.
3. A method according to any of the preceding clauses, wherein the cost function determines control data to minimise the residual of the performance parameter across the plurality of fields.
4. A method according to any of the preceding clauses, wherein the correction comprises actuator control settings for at least one actuator of the lithographic apparatus.
5. A method according to any of the preceding clauses, wherein the control data comprises a routing order for exposure of the plurality of fields.
6. A method according to clause 5, wherein the output comprises a routing order for exposure of the plurality of fields.
7. A method according to any of the preceding clauses, when dependent on clause 2, further comprising determining a preparation time to be provided to the lithographic for implementing control data, wherein the boundary conditions are determined based at least in part on the preparation time.
8. A method according to clause 7, wherein determining a preparation time comprises

determining a residual of a performance parameter for a first preparation time for one or more fields;

determining a residual of a performance parameter for a second preparation time for the one or more fields, wherein the second preparation time is longer than the first preparation time;

selecting one of the first preparation time and the second preparation time as the preparation time to be provided to the lithographic apparatus based on a comparison of the residuals for the first preparation time and the second preparation time to a threshold residual value.

9. A method according to clause 8, wherein the threshold residual value represents an upper limit for a residual resulting in a functioning field.
10. A method for determining an input to a lens model to determine a setpoint for manipulation of a lens of a lithographic apparatus when addressing at least one of a plurality of fields of a substrate, the method comprising:

receiving parameter data for the at least one field, the parameter data relating to one or more parameters of the substrate within the at least one field, the one or more parameters being at least partially sensitive to manipulation of the lens as part of an exposure performed by the lithographic apparatus;

receiving lens model data relating to the lens;

determining the input based on the parameter data and on the lens model data.

11. A method according to clause 10, wherein the at least one field comprises a partial field, and the parameter data comprises parameter data relating to locations inside the partial field;

and wherein determining the input comprises optimizing the input to apply a correction to the one or more parameters, wherein the correction is identified by the parameter data relating to the locations within the partial field.

12. A method according to clause 11, wherein optimizing the input comprises:

determining an initial setpoint inside of the partial field based on a first lens model, wherein the first lens model is based on the lens model data; and

evaluating the initial setpoint to determine a setpoint across a portion for a full field outside of the partial field to determine a target setpoint.

13. A method according to clause 12, wherein the first lens model is further configured to determine an input corresponding to the target setpoint.
14. A method according to any of clauses 12 or 13, wherein the first lens model is a partial field aware lens model configured not to optimize the input for locations outside of the partial field.
15. A method according to any of clauses 11 to 14, wherein optimizing the input comprises:

determining a plurality of provisional inputs based on the parameter data; and

selecting one of the plurality of provisional inputs based on the lens model data.

16. A method according to clause 15, wherein determining one or more of the plurality of provisional inputs comprises extrapolating parameter data outside of the partial field based on the parameter data inside of the partial field.
17. A method according to clause 15 or 16, wherein selecting the one of the plurality of provisional inputs comprises selecting a provisional input that applies a correction to the parameter that is closest to the correction identified from the parameter data.
18. A method according to clause 17, wherein the correction is of an error identified in the parameter data.
19. A method according to any of clauses 10-18, wherein the lens model data comprises a copy of the lens model.
20. A method according to any of clauses 10-19, wherein the lens model data comprises dynamic data for the lens.
21. A method according to any of clauses 10-20, wherein determining the input comprises determining an input for a first field based on an input for a second field.
22. A method according to clause 21, wherein the first field is a partial field and the second field is a full field.
23. A method according to clause 22, wherein the partial field is adjacent to the full field.
24. A method according to any of clauses 21 to 23, wherein the input is further determined based on dynamic data for the lens and/or an importance of the partial field and/or the full field.
25. A method according to clause 24, wherein the importance of the full field is greater than an importance of the partial field.
26. A method according to clause 20 or 21, wherein the importance of the partial field and/or the full field is based on the number of structures to be patterned in the field and/or the dimensions of at least a portion of the structures to be patterned in the field.
27. A method according to any of clauses 22 to 26, wherein determining the input comprises optimizing the input to apply a correction to the parameters in the full field.
28. A method according to clause 27, wherein the parameter data comprises partial field parameter data and full field parameter data, and wherein optimizing the input comprises:

determining an input for the full field based on the full field parameter data; and

determining an input for the partial field based on the partial field parameter data and using the input for the full field as a constraint.

29. A method according to any of clauses 10-28, wherein the parameter data comprises metrology data.
30. A method according to any of clauses 10-29, wherein manipulation of the lens comprises setting a location of one or more lens manipulators, wherein the lens manipulators are configured to apply a deformation to the lens.
31. A method according to any of clauses 10-30, wherein the one or more parameters comprises one or more of overlay data, critical dimension data, levelling data, alignment data, or edge placement error data.
32. A method according to clause 31, wherein the parameter data is associated with one or more of pattern shift, overlay, alignment aberrations, or focus errors.
33. A method according to any of clauses 10-32, further comprising:

providing the input to the lens model; and

determining, based on the lens model, the setpoint for manipulation of the lens.

34. A method according to clause 33, further comprising providing the setpoint to the lens, wherein the lithographic apparatus is configured to perform a lithographic exposure of a substrate using the provided lens setpoint.
35. An apparatus for determining control data for a lithographic apparatus, the apparatus comprising one or more processors configured to perform a method according to any of clauses 1-9.
36. An apparatus for configuring an input to a lens model for determining one or more settings of a lens of a lithographic apparatus, the apparatus comprising one or more processors configured to perform a method according to any of clauses 10 to 34.
37. A lithographic apparatus comprising an apparatus according to clause 35 or 36.
38. A lithographic cell comprising an apparatus according to clause 37.
39. A computer program product comprising computer readable instructions configured to perform, when run on a suitable computer system, the method of any of clauses 1 to 34.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments in the context of a lithographic apparatus, embodiments may be used in other apparatus. Embodiments may form part of a mask inspection apparatus, a metrology apparatus, or any apparatus that measures or processes an object such as a wafer (or other substrate) or mask (or other patterning device). These apparatuses may be generally referred to as lithographic tools. Such a lithographic tool may use vacuum conditions or ambient (non-vacuum) conditions.

Although specific reference may be made in this text to embodiments in the context of an inspection or metrology apparatus, embodiments may be used in other apparatus. Embodiments may form part of a mask inspection apparatus, a lithographic apparatus, or any apparatus that measures or processes an object such as a wafer (or other substrate) or mask (or other patterning device). The term “metrology apparatus” (or “inspection apparatus”) may also refer to an inspection apparatus or an inspection system (or a metrology apparatus or a metrology system). E.g. the inspection apparatus that comprises an embodiment may be used to detect defects of a substrate or defects of structures on a substrate. In such an embodiment, a characteristic of interest of the structure on the substrate may relate to defects in the structure, the absence of a specific part of the structure, or the presence of an unwanted structure on the substrate.

Although specific reference may have been made above to the use of embodiments in the context of optical lithography, it will be appreciated that the invention, where the context allows, is not limited to optical lithography and may be used in other applications, for example imprint lithography.

While the targets or target structures (more generally structures on a substrate) described above are metrology target structures specifically designed and formed for the purposes of measurement, in other embodiments, properties of interest may be measured on one or more structures which are functional parts of devices formed on the substrate. Many devices have regular, grating-like structures. The terms structure, target grating and target structure as used herein do not require that the structure has been provided specifically for the measurement being performed. Further, pitch of the metrology targets may be close to the resolution limit of the optical system of the scatterometer or may be smaller, but may be much larger than the dimension of typical non-target structures optionally product structures made by lithographic process in the target portions C. In practice the lines and/or spaces of the overlay gratings within the target structures may be made to include smaller structures similar in dimension to the non-target structures.

While specific embodiments have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

Although specific reference is made to SXR and EUV electromagnetic radiations, it will be appreciated that the invention, where the context allows, may be practiced with all electromagnetic radiations, includes radio waves, microwaves, infrared, (visible) light, ultraviolet, X-rays, and gamma rays. As an alternative to optical metrology methods, it has also been considered to use X-rays, optionally hard X-rays, for example radiation in a wavelength range between 0.01 nm and 10 nm, or optionally between 0.01 nm and 0.2 nm, or optionally between 0.1 nm and 0.2 nm, for metrology measurements.

1. A method for determining an input to a model to determine a setpoint for manipulation of an optical element of a lithographic apparatus when addressing at least one of a plurality of fields of a substrate, the method comprising:
receiving parameter data for the at least one field, the parameter data relating to one or more parameters of the substrate within the at least one field, the one or more parameters being at least partially sensitive to manipulation of the optical element as part of an exposure performed by the lithographic apparatus;
receiving lens model data relating to the optical element; and
determining the input based on the parameter data and on the model data.

2. The method according to claim 1, wherein the at least one field comprises a partial field, and the parameter data comprises parameter data relating to one or more locations inside the partial field; and
wherein the determining the input comprises optimizing the input to apply a correction to the one or more parameters, wherein the correction is identified by the parameter data relating to the one or more locations within the partial field.

3. The method according to claim 2, wherein the optimizing the input comprises:
determining an initial setpoint inside of the partial field based on a first lens model, wherein the first model is based on the model data; and
evaluating the initial setpoint to determine a setpoint across a portion for a full field outside of the partial field to determine a target setpoint.

4. The method according to claim 3, wherein the first model is further configured to determine an input corresponding to the target setpoint.

5. The method according to claim 3, wherein the first model is a partial field aware lens model configured not to optimize the input for locations outside of the partial field.

6. The method according to claim 2, wherein the optimizing the input comprises:
determining a plurality of provisional inputs based on the parameter data; and
selecting one of the plurality of provisional inputs based on the model data.

7. The method according to claim 6, wherein determining one or more of the plurality of provisional inputs comprises extrapolating parameter data outside of the partial field based on the parameter data inside of the partial field.

8. The method according to claim 6, wherein the selecting the one of the plurality of provisional inputs comprises selecting a provisional input that applies a correction to the parameter that is closest to the correction identified from the parameter data.

9. The method according to claim 8, wherein the correction is of an error identified in the parameter data.

10. The method according to claim 1, wherein the determining the input comprises determining an input for a first field based on an input for a second field, wherein the first field is a partial field and the second field is a full field.

11. The method according to claim 10, wherein determining the input comprises optimizing the input to apply a correction to one or more the parameters in the full field.

12. The method according to claim 1, wherein the one or more parameters comprises one or more selected from: overlay data, critical dimension data, levelling data, alignment data, or edge placement error data.

13. An apparatus for configuring an input to a model for determining one or more settings of an optical element of a lithographic apparatus, the apparatus comprising one or more processors configured to perform the method according to claim 1.

14. A lithographic apparatus comprising the apparatus according to claim 13.

15. A computer program product comprising a non-transitory computer-readable medium having computer readable instructions therein, the instructions, when executed by one or more processors, configured to cause the one or more processors to at least:
receive parameter data for at least one field of a plurality of fields of a substrate, the parameter data relating to one or more parameters of the substrate within the at least one field, the one or more parameters being at least partially sensitive to manipulation of an optical element of a lithographic apparatus as part of an exposure performed by the lithographic apparatus;
receive model data relating to the optical element; and
determine, based on the parameter data and on the model data, an input to a model to determine a setpoint for manipulation of the optical element when addressing the at least field.

16. The computer program product according to claim 15, wherein the at least one field comprises a partial field, and the parameter data comprises parameter data relating to one or more locations inside the partial field; and
wherein the instructions configured cause the one or more processors to determine the input are further configured to cause the one or more processors to optimize the input to apply a correction to the one or more parameters, wherein the correction is identified by the parameter data relating to the one or more locations within the partial field.

17. The computer program product according to claim 16, wherein the instructions configured cause the one or more processors to optimize the input are further configured to cause the one or more processors to:
determine an initial setpoint inside of the partial field based on a first model, wherein the first model is based on the model data; and
evaluating the initial setpoint to determine a setpoint across a portion for a full field outside of the partial field to determine a target setpoint.

18. The computer program product according to claim 16, wherein the instructions configured cause the one or more processors to optimize the input are further configured to cause the one or more processors to:
determine a plurality of provisional inputs based on the parameter data; and
select one of the plurality of provisional inputs based on the model data.

19. The computer program product according to claim 15, wherein the instructions configured cause the one or more processors to determine the input are further configured to cause the one or more processors to determine an input for a first field based on an input for a second field, wherein the first field is a partial field and the second field is a full field.

20. The computer program product according to claim 15, wherein the one or more parameters comprises one or more selected from: overlay data, critical dimension data, levelling data, alignment data, or edge placement error data.
